(19) United States
(12) Patent Application Publication
(10) Pub. No.: US 2002/0196205 A1
(43) Pub. Date: Dec. 26, 2002

(54) Display system

(75) Inventors: Fumiya Yamakado, Tsurugashima-Shi (JP); Takashi Nakano, Tokorozawa-Shi (JP)

Correspondence Address: YOUNG & THOMPSON, 745 SOUTH 23RD STREET 2ND FLOOR, ARLINGTON, VA, 22202

(73) Assignee: PIONEER CORPORATION, TOKYO-TO (JP)

(21) Appl. No.: 10/106,456

(22) Filed: Mar. 27, 2002

(30) Foreign Application Priority Data
Apr. 27, 2001 (JP) 2001-132029

(51) Int. Cl. G09G 3/04; G09G 5/00; G09G 3/30

(52) U.S. Cl. 345/33; 345/1.3; 345/76

(57) ABSTRACT

A display system having a screen-like display unit is disclosed. The display unit is encasable through rolling, and when supplied with display signals corresponding to an image for display thereon, displays such an image. The display system includes driving device, which is located at least one of both ends of the display unit toward which the display unit is rolled, for generating the display signals based on externally supplied image signals and outputting the generated display signals to the display unit.

### BACKGROUND OF THE INVENTION

1. Field of the Invention

The present invention relates generally to display systems, and more particularly to a display system including a screen-like flexible display unit.

2. Description of Related Art

For a meeting involving several persons discussing while viewing specific materials on a display system, typically used as such a display system are, for example, the display of a notebook personal computer, a direct viewing monitor such as a CRT (Cathode Ray Tube) fixed in a meeting room, or a fixed large fabric screen of a projector-type projection system for enlarged presentation.

However, a problem exists that the display of a notebook computer and the direct viewing monitor limit the size of an audience because their display area is small, and this problem may lead to another problem that much expenditure would be entailed if a wide screen display system is arranged as a fixed installation.

Still another problem is that the projector-type projection system, due to its being of a projection viewing configuration, requires a darker environment for sharp and clear presentation and a wide screen such as mentioned above for enlarged presentation.

### SUMMARY OF THE INVENTION

The invention has been made to solve the above problems. An object of the invention is, therefore, to provide a display system which can achieve simplicity in its whole construction, which can be easily carried, and which can provide improved visibility for a large audience.

To achieve the above object, the invention provides a display system having a display unit, which is a screen-like display unit encasable through rolling and which, when supplied with display signals corresponding to an image for display on the display unit, displays the image. The display system comprises driving device such as scanning drivers, located at least one of both ends of the display unit toward which the display unit is rolled, for generating the display signals based on externally supplied image signals and outputting the generated display signals to the display unit.

In this construction, the screen-like display unit is integrated with driver circuit for driving the display unit, whereby a specific image can be displayed only by supplying image signals thereto from an external source. Thus, the display system can achieve simplicity in its whole construction, and can also be easily carried. In addition, the use of the display unit, which is screen-like, contributes to providing improved visibility for a large audience.

In more detailed aspects of the invention, the display unit is rolled into a case, and the at least one end is coupled to rolling mechanism provided within the case, and the driving device is incorporated in the rolling mechanism.

In this construction, the driving device is incorporated in the rolling mechanism, whereby the display system can have improved portability.

In further more detailed aspects of the invention, the at least one end is coupled to support device, such as an unrolling slat, for supporting the display unit while the image is displayed.

In this construction, the end of the display unit including the driving device is coupled to the support device, whereby the display system can have improved portability.

In further more detailed aspects of the invention, connection lines for connecting the driving device to the display unit are arranged on peripheral areas of the display unit.

In this construction, the display unit can have a large displayable area.

In further more detailed aspects of the invention, the display unit is constructed with a plurality of partial display segments which are coupled to one another planewise.

In this construction, a large-sized display unit can be fabricated with ease.

In even more detailed aspects of the invention, connection lines for connecting the driving device to each of the partial display segments are arranged on peripheral areas of the partial display segment.

In this construction, even when the display unit is constructed of a plurality of partial display segments, the display unit can have a large displayable area.

In addition, a plurality of partial display segments are coupled to one another planewise to construct the display unit, whereby the size of the display unit can be increased easily by increasing the number of partial display segments to be coupled.

### BRIEF DESCRIPTION OF THE DRAWINGS

FIG. 1A is a perspective view showing the appearance of a display system according to a first embodiment, when in use;

FIG. 1B is a perspective view showing the appearance of the same when carried;

FIGS. 2A and 2B are diagrams respectively showing detailed constructions of a display unit according to the first embodiment;

FIG. 3 is a diagram showing a circuit configuration of the display system according to the first embodiment;

FIG. 4 is a perspective, transparent view showing a detailed configuration of a case according to the first embodiment;

FIGS. 5A through 5C are internal side views, each showing a detailed configuration of the case according to the first embodiment;

FIG. 6 is a perspective, transparent view showing a detailed configuration of a case according to a second embodiment;

FIG. 7 is a perspective view showing the appearance of a display system according to a first modification;

FIG. 8 is a diagram showing a detailed configuration of a display unit according to a second modification;

FIG. 9 is a perspective view showing the appearance of a display system according to a third modification;

FIG. 10A is a diagram showing the appearance of a display system according to a fourth modification, when in use;

FIG. 10B is a diagram showing the appearance of the same being rolled up; and

FIG. 10C is a diagram showing the appearance of the same when carried.

### DETAILED DESCRIPTION OF THE PREFERRED EMBODIMENTS

Preferred embodiments of the invention will now be described with reference to the drawings.

The following embodiments refer to applications of the invention to, for example, a display system provided with a 50″ diagonal flexible display unit which is rollable into a case described below.

(1) First Embodiment

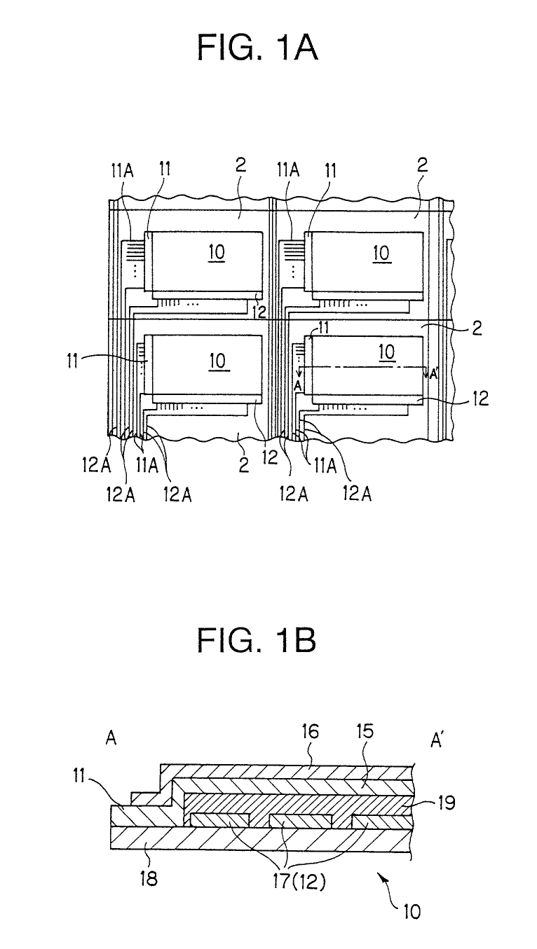

A first embodiment of the invention will be described with reference to FIGS. 1 through 5.

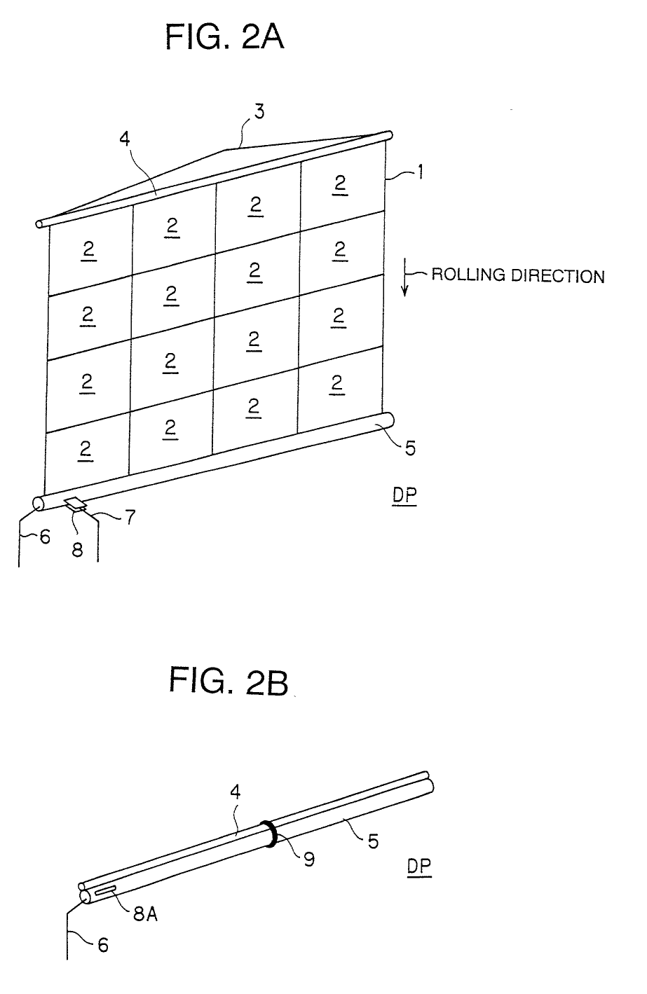

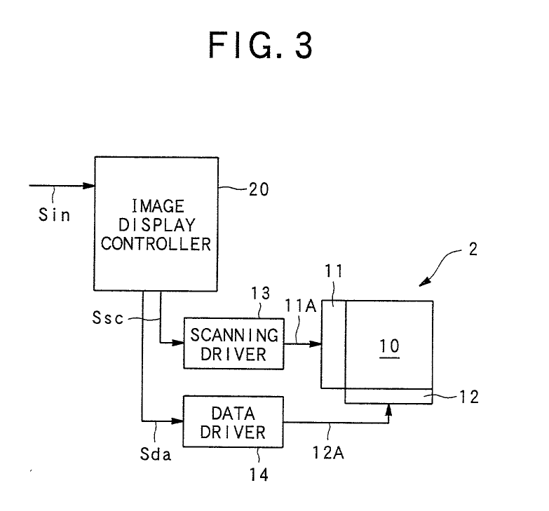

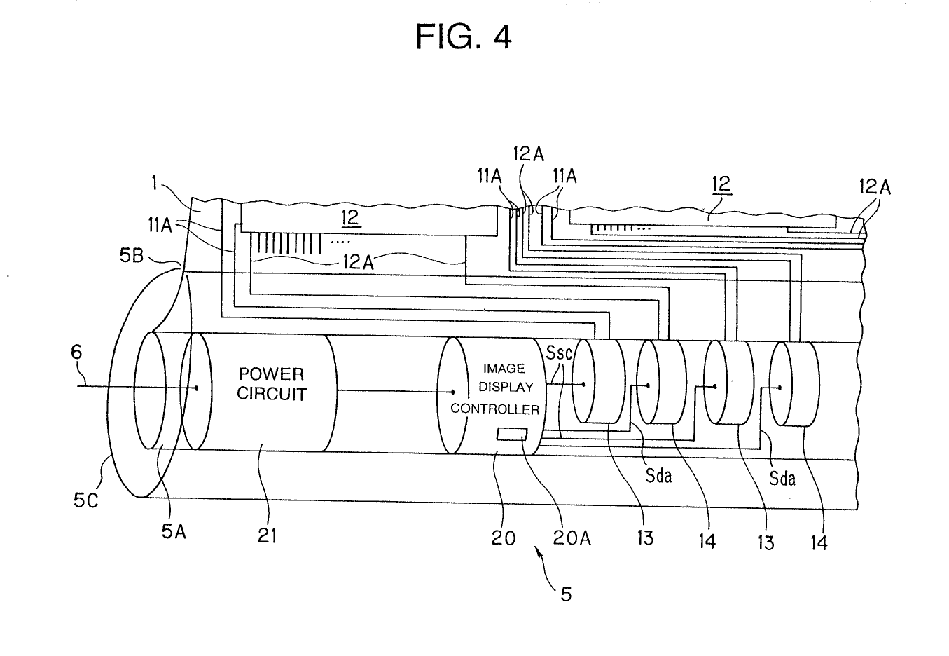

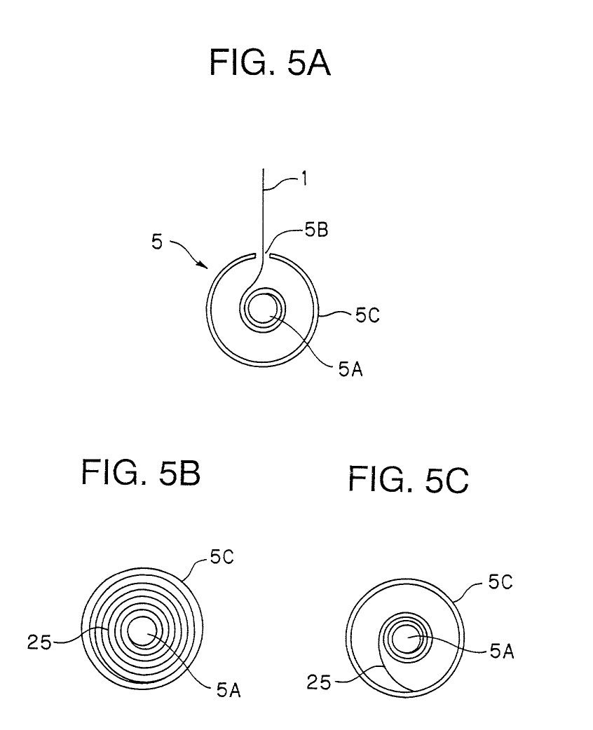

FIG. 1 shows the whole configuration of a display system according to the first embodiment; FIG. 2 shows detailed constructions of a display unit of the display system; FIG. 3 shows a circuit configuration of the display system; and FIGS. 4 and 5 show detailed configurations of a case of the display system.

As shown in FIG. 1A, a display system DP according to the first embodiment comprises a display unit 1, an unrolling slat 4, a hanging cord 3, and a case 5. The display unit 1, which is, for example, a 50″ diagonal display flexible to be rolled into the case 5, is supplied with display signals corresponding to an image for display thereon from driver circuit (described below) to display the image by generating light. The unrolling slat 4 as support device to be gripped by a user to unroll the display unit 1 from the case 5 is coupled to one end of the display unit 1 which is opposite to the other end of the unit 1 for coupling to the case 5. The hanging cord 3, coupled to both ends of the unrolling slat 4, is used to hang the display system DP, for example, from a ceiling or on a wall. The case 5 allows the display unit 1 to be encased therein by rolling, and also incorporates the driver circuit.

The display unit 1 consists of partial display segments 2, each being formed of a single electroluminescent (EL) display device, arranged planewise as well as in a matrix. The driver circuit addresses the display signals to corresponding ones of the partial display segments 2.

A power line 6 is connected to the case 5 to power the driver circuit from an external source. An image signal line 7 is also connected to the case 5 via a connector 8 to supply image signals from a computer or the like to the driver circuit. The image signals serve to generate the display signals and thus correspond to the image for display on the display unit 1.

To carry the display system DP, a user removes the connector 8 from a socket 8A provided in the case 5 together with the image signal line 7, rolls the display unit 1 down into the case 5, and then binds the unrolling slat 4 and the case 5 together with a string 9, so that the display system DP is ready to be carried, as shown in FIG. 1B.

Referring next to FIGS. 2 and 3, the detailed configuration of the display unit 1 will be described.

As shown in FIG. 2A, each of the partial display segments 2, which constitutes the display unit 1, comprises an image display section 10, a cathode lead section 11, an anode lead section 12, and connection lines 11A and 12A. The image display section 10, constructed of a plurality of EL elements, actually displays images. The cathode lead section 11 clusters leads extending from cathodes (described below) which constitute the image display section 10. The anode lead section 12 clusters leads extending from anodes (described below) which also constitute the image display section 10. The connection lines 11A connect the cathode lead section 11 to a corresponding one of scanning drivers within the driver circuit. The connection lines 12A connect the anode lead section 12 to a corresponding one of data drivers within the driver circuit. The connection lines 11A and 12A are respectively connected to the corresponding scanning and data drivers through passage over areas excluding the image display section 10, cathode lead section 11, and anode lead section 12 in the partial display segment 2. The connection lines 11A and 12A are patterned on, for example, a flexible board bonded by pressure onto the image display section 10.

Referring next to FIG. 2B, detailed constructions of the image display section 10, etc. will be described. FIG. 2B is a partial sectional view taken along a line A-A′ of FIG. 2A.

As shown in FIG. 2B, the image display section 10 comprises the anodes 17, a plurality of organic layers 19, the cathodes 15, and a moisture-resistant resin board 16, which are laminated on a transparent, moisture-resistant board 18. The anodes 17 extend in the form of parallel stripes. The organic =layers 19 provide luminous sections for red (R), green (G), and blue (B) which are laminated one upon another in the form of stripes orthogonally crossing the anodes 17. The cathodes 15 similarly extend in the form of parallel stripes orthogonally crossing the anodes 17. The resin substrate 16 may not necessarily be transparent, but may preferably be a black or other colored layer in order for the display unit 1 to achieve better contrast.

Each EL element as a luminous section is formed at a location where one of the anodes 17 crosses one of the cathodes 15. Such EL elements are assembled into a matrix to form each image display section 10. The resin substrate 18 is the display side. The cathodes 15 constitute the cathode lead section 11 at one end thereof, and the anodes 17 constitute the anode lead section 12 at one end thereof.

Referring next to FIG. 3, the electrical circuit, etc. of the image display section 10 will be described. FIG. 3 is a block diagram showing a circuit configuration relevant only to one of the partial display segments.

Image signals Sin corresponding to an image for display on the display unit 1 are supplied to an image display controller 20 described below, which is provided within the case 5, via the image signal line 7 and the connector 8.

The image display controller 20 generates scanning signals Ssc and data signals Sda, and supplies the generated signals Ssc and Sda to the corresponding scanning and data drivers 13 and 14 in the driver circuit for further application to the corresponding cathode and anode lead sections 11 and 12 as the display signals, respectively.

The scanning driver 13 subjects the received scanning signals Ssc to prescribed processes including amplification, and supplies the processed signals Ssc to the cathode lead section 11 via the corresponding connection lines 11A.

The data driver 14 similarly subjects the received data signals Sda to prescribed processes including amplification, and supplies the processed signals Sda to the anode lead section 12 via the corresponding connection lines 12A.

Every time the scanning signals Ssc and the data signals Sda are supplied to the cathode lead section 11 and the anode lead section 12, respectively, the image display section 10 as the partial display segment are driven to display the image on the surface of the resin substrate 18 as part of the display unit 1.

Referring then to FIG. 4, the configuration of the case 5 according to the first embodiment will be described.

FIG. 4 shows an internal structure of the case 5.

As shown in FIG. 4, the case 5 comprises a tubular chassis 5C having a slit 5B that runs its entire length, and a roller 5A supported rotatably with respect to the chassis 5C and coupled to one end of the display unit 1 which is opposite to the other end of the unit 1 for coupling to the unrolling slat 4.

Incorporated in a cylindrical space within the roller 5A are a power circuit 21, the image display controller 20, the scanning drivers 13, and the data drivers 14. The power circuit 21, connected to the power line 6 (see FIG. 1), supplies power for driving the display unit 1. The image display controller 20, which is cylindrically shaped, receives power from the power circuit 21 and includes a socket 20A for connection to the connector 8. Each scanning driver 13 as a cylindrically-shaped driving device is connected to the corresponding connection lines 11A, receives the scanning signals Ssc from the image display controller 20, and supplies the received signals Ssc to the corresponding cathode lead section 11. Each data driver 14 as a cylindrically-shaped driving device is connected to the corresponding connection lines 12A, receives the data signals Sda from the image display controller 20, and supplies the received signals Sda to the corresponding anode lead section 12. In this configuration, the roller 5A contains as many scanning drivers 13 and data drivers 14 as the partial display segments 2 therein. The whole part of the display unit 1 is rolled into the case 5 when the roller 5A rotates in a manner described below, while the display unit 1 is coupled to the roller 5A at one end thereof.

In some embodiments, the power circuit 21 may be, for example, an Ac-to-Dc converter circuit including a transformer, a rectifier, and a smoothing capacitor.

The socket 20A is arranged to become aligned with the socket 8A formed in the chassis 5C under the condition that the display unit 1 is fully unrolled from the case 5. Thus, under this condition, the connector 8 is directly connected to the socket 20A when inserted into the socket 8A from outside the chassis 5C, and thus connection can be established between the image display controller 20 and the connector 8.

Referring next to FIG. 5, how the display unit 1 is rolled into the case 5 will be described.

FIG. 5 is a side view schematically showing a rolling mechanism as viewed from the power line 6 connecting end of the case 5.

As shown in FIG. 5A, and as described above, the display unit 1 is coupled at one end thereof to the roller 5A via the slit 5B formed in the tubular chassis 5C of the case 5. Thus, the display unit 1 is rolled into the chassis 5C when the roller 5A is rotated.

As shown in FIGS. 5B and 5C, a spiral spring 25 is provided at one end of the chassis 5C. The spring 25 is coupled at one end thereof to the roller 5A and at the other end thereof to the inside of the chassis 5C. FIG. 5B shows the display unit 1 encased in the chassis 5C, with the spiral spring 25 extended, while FIG. 5C shows the display unit 1 unrolled from the chassis 5C, with the spring 25 compressed.

A unidirectional clutch (not shown), which is disengageable from outside, is provided within the chassis 5C to lock the display unit 1 unrolled from the chassis 5C against rolling back into the chassis 5C. Upon disengagement of the unidirectional clutch, the tension of the spiral spring 25 drives the display unit 1 to be rolled upon the roller 5A as rolling mechanism within the chassis 5C.

It should be understood that disengagement of the unidirectional clutch may be controlled by changing the angle of unrolling the display unit 1 in relation to the chassis 5C, similarly to conventional rolling screen systems.

As described in the foregoing, in the display system DP according to the first embodiment, the screen-like display unit 1 is integrated with the scanning drivers 13, etc. for driving the display unit 1, whereby a desired image can be displayed only by supplying image signals Sin from an external source. Hence, the display system DP can achieve simplicity in its whole construction, and can also be easily carried. In addition, the use of the screen-like display unit 1, which is of a light-generating configuration, not of a projection configuration, contributes to providing improved visibility for a large audience.

Moreover, the scanning drivers 13, etc. are incorporated in the roller 5A within the case 5, whereby the display system DP can have improved portability.

Furthermore, the connection lines 11A and 12A for connecting the scanning drivers 13, etc. to the display unit 1 are arranged on peripheral areas of the display unit 1, whereby the display unit 1 can increase its displayable area.

Furthermore, the connection lines 11A and 12A for connecting the scanning driver 13, etc. to the display unit 1 are arranged on peripheral areas of each partial display segment 2, whereby the display unit 1 can increase its displayable area even when the display unit 1 is formed of a plurality of partial display segments 2.

Furthermore, a plurality of partial display segments 2 are coupled to one another planewise to construct the display unit 1, whereby a large-sized display unit 1 can be implemented by increasing the number of partial display segments to be coupled.

More specifically, some restriction may be imposed on the size of a display unit 1 if a system, such as a vacuum film-forming system, is employed for simultaneous production of multiple display units, and this restriction on the simultaneously producible size further imposes a restriction on the size of the display unit 1 which can be increased. In addition, a certain increase in the size of the display unit 1 is likely to reduce production yield. However, the display unit 1 according to the first embodiment in which a plurality of partial display segments 2 are coupled to one another planewise can eliminate the above restrictions to allow the size of the display unit to be easily increased.

(II) Second Embodiment

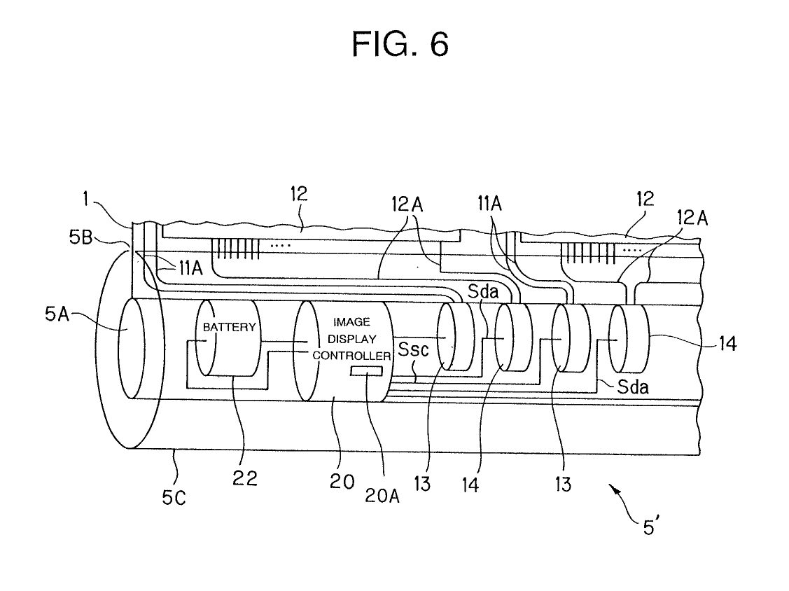

A second embodiment of the invention will be described with reference to FIG. 6, which is a perspective, transparent view showing the internal structure of a case.

Unlike the first embodiment in which the display unit 1 is powered via the power line 6 external thereto, in the second embodiment, the display unit 1 is powered by a battery contained in the roller 5A. In a display system according to the second embodiment, the same parts and components as those of the first embodiment are denoted by the same reference numerals, and their detailed description is omitted.

Referring to FIG. 6, a case 5′ according to the second embodiment includes a chargeable or replaceable battery 22 in place of the power circuit 21 within the case 5 according to the first embodiment. The battery 22 supplies required power to the image display controller 20.

Since the other components in the second embodiment are substantially the same as those of the case 5 according to the first embodiment, their detailed description is also omitted.

As described above, in the case 5′ of the display system according to the second embodiment, power is supplied by the battery 22, whereby advantages similar to those provided by the display system DP according to the first embodiment can be obtained, and in addition, the power line 6 is eliminated to further improve the portability of the display system DP.

(III) Modified Embodiments

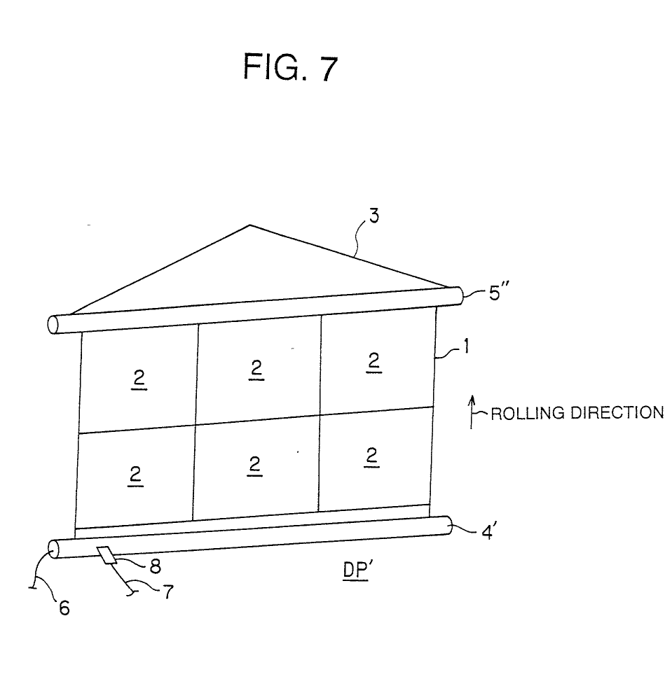

Referring next to FIGS. 7 through 9, modified embodiments of the invention will be described.

In FIGS. 7 through 9, components similar to those of the display system according to the first or the second embodiment are denoted by similar reference numerals, and their detailed description is omitted.

First, unlike the first or the second embodiment in which the driver circuit is provided in the roller 5A within the case 5 or 5′, in a first modification, a case 5″ for encasing the display unit 1 therein by rolling is provided on the upper side of a display system DP′ and an unrolling slat 4′ for unrolling the display unit 1 from the case 5″ is provided on the lower side of the system DP, according to a view of FIG. 7 showing the display system DP in use. In this modification, the hanging cord 3 is coupled to both ends of the case 5″, and the driver circuit, previously described with reference to FIG. 4 or 6, is incorporated in a cylindrical space within the unrolling slat 4′ which is located on the lower side, according to the same view of FIG. 7.

Moreover, as shown in FIG. 7, the power line 6 and the connector 8 are connected to the unrolling slat 4″ for unrolling the display unit 1 from the case 5″ if the first modification is to be derived from the first embodiment.

According to this modification, the display unit 1 is coupled to the unrolling slat 4′ that incorporates the driver circuit therein, the roller 5A is no longer restricted by the space for the driver circuit and thus can have a smaller inner diameter, whereby the display system can be implemented with improved portability.

In a second modification, unlike the first and second embodiments in which the display unit 1 is constructed of a plurality of partial display segments 2 coupled to one another planewise, a display unit 1′ may be constructed of a single EL display device comprising the image display section 10, the cathode lead section 11, the anode lead section 12, and the connection lines 11A and 12A, as shown in FIG. 8.

In this modification, if it is to be derived, for example, from the first embodiment, the display unit 1′ constructed of a single EL display device is rolled into the case 5, and the driver circuit for driving the EL display device is incorporated in the roller within the case 5.

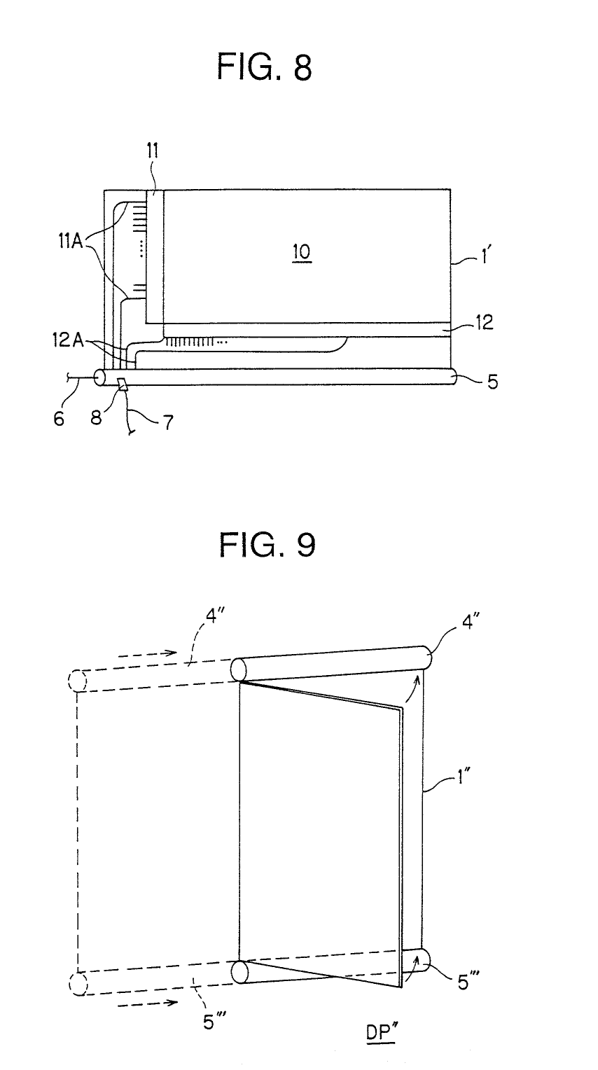

Furthermore, in a third modification, a display system DP″ includes the unrolling slat and the case which are telescopic so that the unrolling slat and the case can be expanded when in use and contracted when carried as shown in FIG. 9. When the display system DP″ is carried, a display unit 1″ is folded into halves at the middle to be rolled into a case 5′″.

In this modification, the driver circuit is incorporated in a space within the roller which is equivalent to the contracted case 5′″, and the display unit 1″ is constructed of one (in the case of the second modification) or more EL display devices (in the case of the first or the second embodiment). Moreover, the connection lines are connected to the driver circuit incorporated in the roller that is contracted.

Furthermore, in a fourth modification, unlike the above-described embodiments and modifications in which the display unit 1, etc. are rolled into the case 5, etc., the display unit 1 is merely rolled upon the unrolling slat 4, instead of being rolled into the case 5, etc., and then a tape or the like is tied around the unrolling slat 4 on which the display unit 1 is rolled, for example, when the fourth modification is to be derived from the first embodiment.

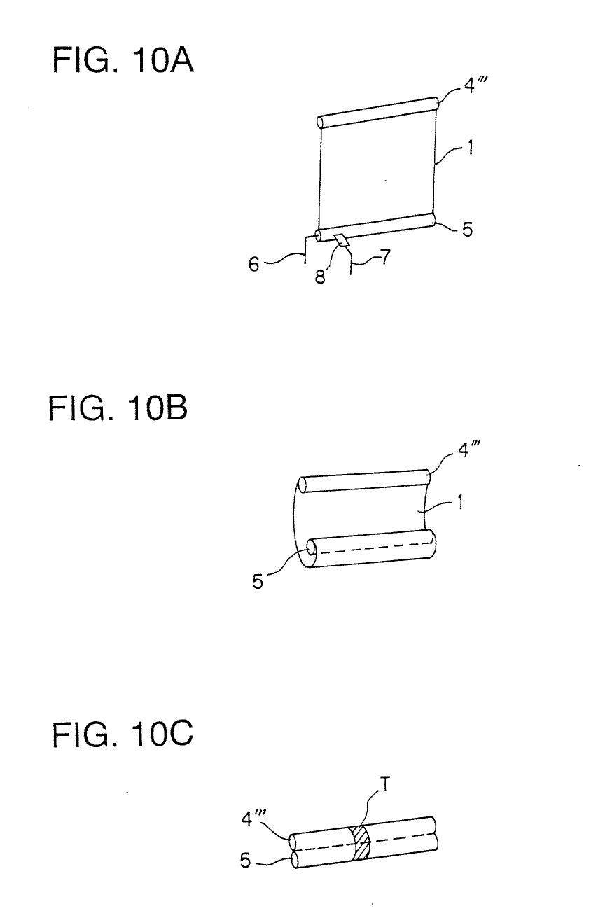

More specifically, as shown in FIG. 10A, for example, the power line 6 and the image signal line 7 are removed from the display system in use with the display unit 1 stretched out, and the display unit 1 is rolled up onto an unrolling slat 4′″ from the side of the case 5 (see FIG. 10B), after which both the unrolling slat 4″. and the case 5 are bound together with a tape T (FIG. 10C), whereby the display system is ready to be carried.

In a fifth modification, only the power circuit 21 in the first embodiment may be provided outside the case 5 as a separate component to have the image display controller within the case 5 powered externally. In this modification, the case 5 can be further downsized to be carried more easily.

These modifications can likewise provide advantages similar to those provided by the above embodiments.

Furthermore, in addition to the above embodiments and modifications in which the display unit comprises one or more EL display devices, the invention can be extensively applied to various other display systems having a display unit, such as a screen-like display unit constructed of one or more display devices of any other type than the above, as long as such a display device is flexible.

The invention may be embodied in other specific forms without departing from the spirit or essential characteristics thereof. The present embodiments are therefore to be considered in all respects as illustrative and not restrictive, the scope of the invention being indicated by the appended claims rather than by the foregoing description and all changes which come within the meaning and range of equivalency of the claims are therefore intended to be embraced therein.

The entire disclosure of Japanese Patent Application No. 2001-132029 filed on Apr. 27, 2001 including the specification, claims, drawings and summary is incorporated herein by reference in its entirety.

What is claimed is:

1. A display system comprising:
a display unit, which is a screen-like display unit encasable through rolling and which, when supplied with display signals corresponding to an image for display on said display unit, displays said image;
a driving device, located at least one of both ends of said display unit toward which said display unit is rolled, for generating said display signals based on externally supplied image signals and outputting said generated display signals to said display unit.

2. A display system according to claim 1, wherein
said display unit is rolled into a case;
said at least one end is coupled to rolling mechanism provided within said case; and
said driving device is incorporated into said rolling mechanism.

3. A display system according to claim 1, wherein
said at least one end is coupled to support device for supporting said display unit while said image is displayed.

4. A display system according to claim 1, wherein
connection lines for connecting said driving device to said display unit are arranged on peripheral areas of said display unit.

5. A display system according to claim 2, wherein
connection lines for connecting said driving device to said display unit are arranged on peripheral areas of said display unit.

6. A display system according to claim 3, wherein
connection lines for connecting said driving device to said display unit are arranged on peripheral areas of said display unit.

7. A display system according to claim 1, wherein
said display unit is constructed with a plurality of partial display segments which are coupled to one another planewise.

8. A display system according to claim 2, wherein
said display unit is constructed with a plurality of partial display segments which are coupled to one another planewise.

9. A display system according to claim 3, wherein
said display unit is constructed with a plurality of partial display segments which are coupled to one another planewise.

10. A display system according to claim 7, wherein
connection lines for connecting said driving device to each of said partial display segments are arranged on peripheral areas of said partial display segment.

11. A display system according to claim 8, wherein
connection lines for connecting said driving device to each of said partial display segments are arranged on peripheral areas of said partial display segment.

12. A display system according to claim 9, wherein
connection lines for connecting said driving device to each of said partial display segments are arranged on peripheral areas of said partial display segment.
